(19) United States
(12) Patent Application Publication
(10) Pub. No.: US 2025/0255065 A1
(43) Pub. Date: Aug. 7, 2025

(54) UNIT SUB-PIXEL STRUCTURE OF MICRO-LED AND METHOD OF MANUFACTURING THE SAME

(71) Applicant: SUNDIODE, INC., Sunnyvale, CA (US)

(72) Inventors: James Chinmo KIM, Mountain View, CA (US); Sungsoo YI, Sunnyvale, CA (US)

(21) Appl. No.: 19/041,953

(22) Filed: Jan. 30, 2025

(30) Foreign Application Priority Data
Feb. 5, 2024 (KR) 10-2024-0017155

(51) Int. Cl. H10H 29/14; H10H 29/01; H10H 29/80

(52) U.S. Cl. CPC H10H 29/142; H10H 29/011; H10H 29/842; H10H 29/942

(57) ABSTRACT

Disclosed is a structure of a unit sub-pixel having a size of several microns or tens of microns divided into a plurality of light emitters and connected to each other so that the divided light emitters are diode-connected, and a manufacturing method thereof. By increasing the operating voltage to multiples of voltage values near the turn-on voltage of a single light emitter, power-consumption efficiency is increased, and light efficiency is increased.

### TECHNICAL FIELD

The present inventive concept is related to a sub-pixel configuring a unit pixel of a micro-LED, and more particularly to a structure of a sub-pixel of a micro-LED having a plurality of light emitters connected in series to improve light efficiency, and to a manufacturing method thereof.

### BACKGROUND ART

Micro-LEDs are display devices composed of tiny pixels ranging in size from a few microns to tens of microns in diameter. A unit pixel is composed of R (red), G (green), and B (blue) subpixels, which are also a few microns to tens of microns in size. The smaller the sub-pixel or unit pixel size, the higher the resolution of the display.

In addition, the unit pixel, which is the unit constituent of the display, is required to be highly energy efficient. Each sub-pixel has the structure of a light-emitting diode (LED). Since it has a diode in an equivalent circuit, the turn-on voltage is determined by the diode operation, and when a voltage higher than the turn-on voltage is applied, the brightness of the sub-pixel is greatly increased. In other words, the sub-pixel has the typical diode characteristics, so the brightness is controlled by the current flowing through the diode due to biasing above the turn-on voltage. For sub-pixels that are a few to a few tens of microns in size, turn-on voltage can vary depending on the color of the light generated and stacking structure but is typically between 2 V and 3 V. This is a fairly low voltage for display applications, and driving sub-pixels in this voltage range can result in increased power consumption.

The main reason for the increased power consumption is Joule heating. Since Joule heating is expressed as I²R, as the current increases, Joule heating also increases, and the current responsible for the Joule heating cannot participate in the light-emitting behavior.

In addition, when the size of the sub-pixel is reduced, the electrons and holes that participate in the light-emitting behavior can more easily move to the sidewalls of the sub-pixel and non-radiatively recombine, thus resulting in reduced light-emitting efficiency.

As an alternative, a method of applying a relatively high voltage to a sub-pixel that is a light-emitting diode is presented. To apply a high voltage to micro-sized subpixels, it is necessary to dispose the sub-pixels and connect them in series. To place sub-pixels emitting the same color in the same plane, a transfer process must be performed, but it is not easy to transfer sub-pixels having very small sizes, and significant process failures can occur during the transfer process.

### DISCLOSURE

### Technical Problem

The present inventive concept is directed to provide a unit sub-pixel having an increased operating voltage by separating a pixel into a plurality of unit sub-pixels and connecting them in series.

Furthermore, the present inventive concept is directed to provide a method for manufacturing a unit sub-pixel having an increased operating voltage.

### Technical Solution

One aspect of the present inventive concept provides a unit sub-pixel having a square shape, the unit sub-pixel comprising a first light emitter electrically connected to an anode connected to an external power source, a second light emitter having the shape of the first emitter rotated by 90 degree, formed in a region adjacent to the first light emitter and electrically connected to the first light emitter, a third light emitter having the shape of the second emitter rotated by 90 degrees, formed in a region adjacent to the second light emitter and electrically connected to the second light emitter, and a fourth light emitter having the shape of the third emitter rotated by 90 degrees, formed in a region adjacent to the third light emitter, and electrically connected to the third light emitter.

The four light emitters form light of the same wavelength, and the first and second light emitters are opposite to the third and fourth light emitters.

Another aspect of the present inventive concept provides a unit sub-pixel comprising light emitters formed on the same substrate, respectively having an n-type semiconductor layer, an active layer and a p-type semiconductor layer, and separated from each other, a first insulating layer covering the upper portion of the light emitters and burying gap spaces between the light emitters, a wiring layer penetrating the first insulating layer or formed on the first insulating layer to diode-connect the light emitters, a second insulating layer formed on the wiring layer and on the first insulating layer, and an electrode layer connecting the light emitters to external power.

Still another aspect of the present inventive concept provides a method of manufacturing a unit sub-pixel. The method comprises sequentially forming a n-type semiconductor layer, an active layer and a p-type semiconductor layer on substrate, forming light emitters by etching and separating the n-type semiconductor layer, the active layer and the p-type semiconductor layer, performing a wiring process in which the n-type semiconductor layer of the light emitter is connected to the p-type semiconductor layer of another light emitter adjacent to the light emitter, and after the wiring process, performing an electrode-forming process in which an anode is formed on the p-type semiconductor layer of the light emitter and a cathode is formed on n-type semiconductor layer of the light emitter at a tail-end adjacent to the light emitter.

### Advantageous Effects

According to the present inventive concept, a roughly rectangular unit sub-pixel is divided into four light emitters having the same area. The four divided light emitters are electrically connected in series. Thus, the voltage for turning on one unit sub-pixel has a higher voltage value than for the case where it is not divided. If the turn-on voltage of a unit sub-pixel is increased, power-consumption efficiency of the unit sub-pixel is increased. Furthermore, optical efficiency is also increased.

The present inventive concept described can improve power-consumption efficiency of a unit sub-pixel, which is an element of a unit pixel of the micro-LED. Furthermore, a wiring layer and an electrode layer are formed on top of the at least one light emitter, and the light generated by the light emitter is reflected by the electrode layer and directed toward the substrate. This is a type of flip-chip design, and light can be effectively emitted through the substrate. In addition, as the unit sub-pixel is separated and due to the wiring scheme, the operating voltage of the unit sub-pixel can be easily increased because a transfer processing of a plurality of individual light emitters is not required.

Effects of the present inventive concept are not limited to the above-described effects, and other unmentioned effects may be clearly understood by those skilled in the art from the following descriptions.

### DESCRIPTION OF DRAWINGS

FIGS. 1A and 1B are, respectively, a top plan view and a cross-sectional view of a sub-pixel according to a preferred embodiment of the present inventive concept.

FIGS. 2A to 14B are top plan views and cross-sectional views for illustrating a method of manufacturing the sub-pixel of FIG. 1 according to a preferred embodiment of the present inventive concept.

### MODES OF THE INVENTIVE CONCEPT

Hereinafter, embodiments of the present inventive concept will be described in detail with references to the accompanying drawings.

While the present inventive concept is susceptible to various modifications and alternative forms, specific embodiments thereof are shown by way of examples in the drawings and will herein be described in detail. However, it should be understood that there is no intent to limit the inventive concept to the particular forms disclosed, but rather the inventive concept is to cover all modifications, equivalents, and alternatives falling within the spirit and scope of the inventive concept defined by the appended claims.

When an element such as a layer, a region, and a substrate is referred to as being disposed “on” another element, it should be understood that the element may be directly formed on the other element or an intervening element may be interposed therebetween.

It should be understood that, although the terms “first,” “second,” etc. may be used herein to describe various elements, components, areas, layers, and/or regions, these elements, components, areas, layers, and/or regions are not limited by these terms.

### Embodiment

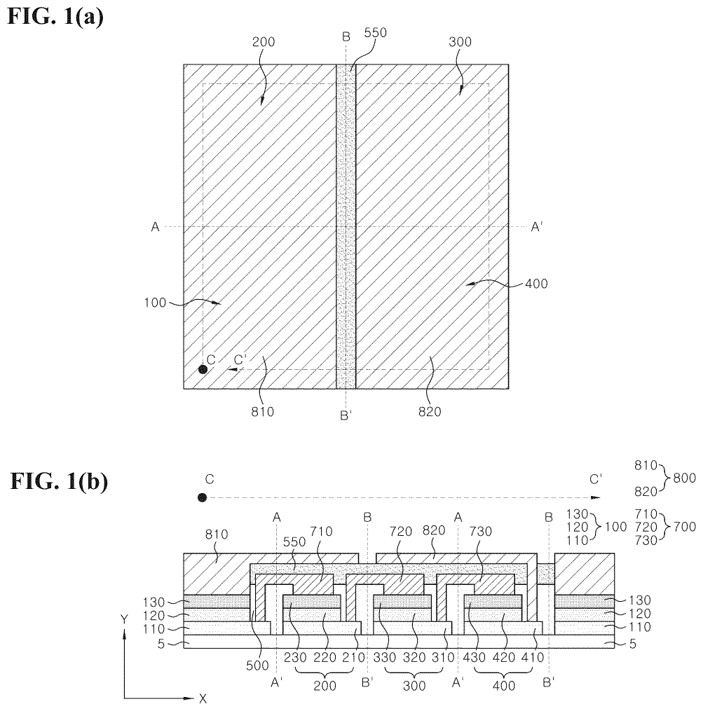

FIG. 1 is a top plan view and a cross-sectional view of a sub-pixel according to a preferred embodiment of the present inventive concept.

Referring to FIG. 1, FIG. 1(a) illustrates a top plan view of a sub-pixel. In the top plan view, two dashed lines A-A′ and B-B′ intersect at the center of the sub-pixel perpendicularly to each other. A-A′ is stretched in the x-axis direction and B-B′ is stretched in the y-axis direction.

FIG. 1(b) is a cross-sectional view of the FIG. 1(a) cut along the direction of the arrows. In FIG. 1(b), one sub-pixel has a first light emitter 100, a second light emitter 200, a third light emitter 300, and a fourth light emitter 400 formed on the substrate 5. The four light emitters 100, 200, 300, 400 produce the same color, and each light emitter has a buffer layer (not shown), an n-type semiconductor layer 110, 210, 310, 410, an active layer 120, 220, 320, 420, and a p-type semiconductor layer 130, 230, 330, 430 on the substrate 5. Current-spreading layer (not shown) such as ITO may be formed on each of the p-type semiconductor layers 130, 230, 330, 430.

Each of the light emitters 100, 200, 300, 400 has a mesa structure in which the n-type semiconductor layers 110, 210, 310, 410 are exposed. Therefore, the p-type semiconductor layers 130, 230, 330, 430 and the active layers 120, 220, 320, 420 of one light emitter 100, 200, 300, 400 have the same profile, and the n-type semiconductor layers 110, 210, 310, 410 have a shape different from them. That is, in each of the light emitters 100, 200, 300, 400, a portion of the p-type semiconductor layer and the active layer is etched to expose a portion of the n-type semiconductor layer 110, 210, 310, 410.

In addition, the current-spreading layer may be formed on the p-type semiconductor layer 130, 230, 330, 430 in the present inventive concept, and as will be described below, when the p-type semiconductor layer 130, 230, 330, 430 is exposed or connected with other components, the current-spreading layer that may optionally be formed on the p-type semiconductor layer 130, 230, 330, 430 may also be exposed or connected with other components.

The substrate 5 may be sapphire, Si or GaAs, and preferably has the same type of crystal structure as the compound semiconductor formed on top of the substrate 5. If the four light emitters 100, 200, 300, 400 emit blue or green color, the substrate 5 may be sapphire. Furthermore, if the four light emitters 100, 200, 300, 400 emit red light, the substrate 5 may be GaAs.

Four neighboring but separate and mutually spaced-apart light emitters 100, 200, 300, 400 are disposed on the substrate 5. The first light emitter 100 to the fourth light emitter 400 are named clockwise from the bottom left corner of the figure (a).

An anode 810 is formed on the first p-type semiconductor layer 130 of the first light emitter 100. The anode 810 is formed by covering the top of the second light emitter 200 from the top of the first light emitter 100. If a current-spreading layer is provided on the p-type semiconductor layer, the anode 810 is formed on the current-spreading layer on the first p-type semiconductor layer 130.

Further, a cathode 820 is formed on the fourth n-type semiconductor layer 410 of the fourth light emitter 400 adjacent to the first light emitter 100 in the x-axis direction. The cathode 820 is formed covering the fourth light emitter 400 and the third light emitter 300.

Preferably, the anode 810 and cathode 820 are opposed to each other around a straight-line B-B′, have a mutually symmetrical formation, and have substantially the same area.

The separating space between the four light emitters 100, 200, 300, 400 is filled with a first insulating layer 500. The first insulating layer 500 may be formed extending to the edge of the p-type semiconductor layer 130, 230, 330, 430 or the current-spreading layer, which is the top layer of the four light emitters 100, 200, 300, 400.

A wiring layer 700 is formed on the first insulating layer 500 or through the first insulating layer 500. The wiring layer 700 has a first wiring 710, a second wiring 720, and a third wiring 730. The first wiring 710 penetrates the first insulating layer 500, contacts the surface of the first n-type semiconductor layer 110, is stretched on the first interlayer insulating film 500, and is formed on the second p-type semiconductor layer 230 of the second light emitter 200 by penetrating the first insulating layer 500. The first n-type semiconductor layer 110 of the first light emitter 100 and the second p-type semiconductor layer 230 of the second light emitting layer 200 are electrically connected via the first wiring 710. The second wiring 720 penetrates the first insulating layer 500 and extends upwardly thereof the first insulating layer 500 to electrically connect the second n-type semiconductor layer 210 of the second light emitter 200 and the third p-type semiconductor layer 330 of the third light emitter 300. Further, a third wire 730 penetrates the first insulating layer 500 and extends upwardly thereof to electrically connect the third n-type semiconductor layer 310 of the third light emitter 300 and the fourth p-type semiconductor layer 430 of the fourth light emitter 400.

A second insulating layer 550 is formed on the first insulating layer 500 and the wiring layer 700. The second insulating layer 550 completely shields the wiring layer 700, and also completely covers the first insulating layer 500 exposed by the wiring layer 700.

The electrode layer 800 includes an anode 810 and a cathode 820, and external power is connected through the anode 810 and the cathode 820. The anode 810 is formed on the first p-type semiconductor layer 130 of the first light emitter 100 by penetrating the first insulating layer 500 and the second insulating layer 550. The anode 810 is formed across an upper portion of the second insulating layer 550 and preferably covers an upper portion of the first light emitter 100 and the second light emitter 200.

The cathode 820 penetrates the first insulating layer 500 and the second insulating layer 550 to contact the fourth n-type semiconductor layer 410 of the fourth light emitter 400. However, since the first insulating layer 500 is formed on the sidewalls of the fourth active layer 420 and the fourth p-type semiconductor layer 430 of the fourth light emitter 400, the cathode 820 and the fourth active layer 420 are not in direct electrical contact. The cathode 820 is formed on the second insulating layer 550 and preferably covers the third light emitter 300 and the fourth light emitter 400.

With the structure described above, the first light emitter 100 to the fourth light emitter 400 implement an equivalent circuit of four diodes connected in series. In practice, the four light emitters 100, 200, 300, 400 are arranged in a unit sub-pixel of rectangular or square shape. Each of the light emitters 100, 200, 300, 400 is physically separated and electrically connected via a wiring layer 700. In addition, a first insulating layer 500 is introduced between the wiring layer 700 and the sidewalls of the light emitters 100, 200, 300, 400 to prevent the sidewalls of the light emitters 100, 200, 300, 400 from being short-circuited with the wiring layer 700. Furthermore, the unit sub-pixels and external power are electrically connected via anode 810 and cathode 820. Thus, the four light emitters 100, 200, 300, 400 can also be modeled as a single diode.

In the above structure, the first light emitter 100 is the light emitter at the fore-end and is powered through the anode 810, and the fourth light emitter 400 is the light emitter at the tail-end and is grounded through the cathode 820. Between the first and last light emitters are the second light emitter 200 and the third light emitter 300, which are connected to each other via the wiring layer 700.

Furthermore, since the four light emitters 100, 200, 300, and 400 are formed from the same LED structure grown on the same substrate by the same process, they form the same color, and the turn-on voltage values of the light emitters can be substantially the same.

Typically, a light emitting diode of a few hundred microns in size has a turn-on voltage of about 3V, where the turn-on voltage may increase somewhat as the size of the light emitting diode decreases. The unit sub-pixels used for micro-LEDs are several to tens of microns in size, have turn-on voltages between 2V and 4V, and suffer from lower light efficiency due to the small size. In order to improve light efficiency, the turn-on voltage of the unit sub-pixel may be increased. When the turn-on voltage increases while the current is maintained, the power applied to the light-emitting diode increases while maintaining the current, thus resulting in increased power at the same current. The increased power is due to the increased voltage, which can be easily understood through the formula power=voltage×current. Thus, the efficiency of the light-emitting diode's power dissipation is increased, and the light efficiency is increased.

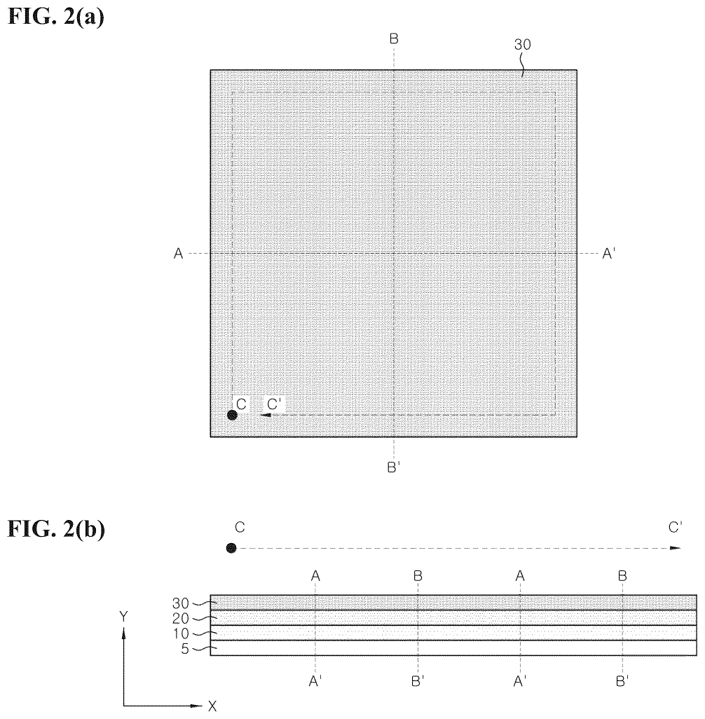

FIGS. 2 to 12 are top plan views and cross-sectional views for illustrating a method of manufacturing the sub-pixel of FIG. 1 according to a preferred embodiment of the present inventive concept.

Referring to FIG. 2, a suitable deposition method such as MOCVD is used on a substrate 5, and a buffer layer (not shown), an n-type semiconductor layer 10, an active layer 20, and a p-type semiconductor layer 30 are formed sequentially. The buffer layer may be optionally introduced, and the composition of the n-type semiconductor layer 10, the active layer 20, and the p-type semiconductor layer 30 is selected according to the color of the light to be implemented. In the case of blue light or green light, a compound semiconductor of GaN or InGaN may be introduced, and in the case of red light, a compound semiconductor of InGaN or AlGaInP may be introduced.

Furthermore, on the p-type semiconductor layer 30, a current-spreading layer may be further introduced.

Referring now to FIG. 2, FIG. 2(a) is a top plan view, and FIG. 2(b) is a cross-sectional view cut along an arrow shown at one periphery of the top plan view. In the following drawings, any reference to FIG. 2(a) refers to the top plan view and any reference to FIG. 2(b) refers to a cross-sectional view cut along an arrow line.

As described in FIG. 1 above, an imaginary line A-A′ is set that is stretched in the x-direction by a length that is approximately square unit sub-pixel, and an imaginary line B-B′ is set that is orthogonal thereto. In the following figures, the two imaginary lines are also used to illustrate the present inventive concept.

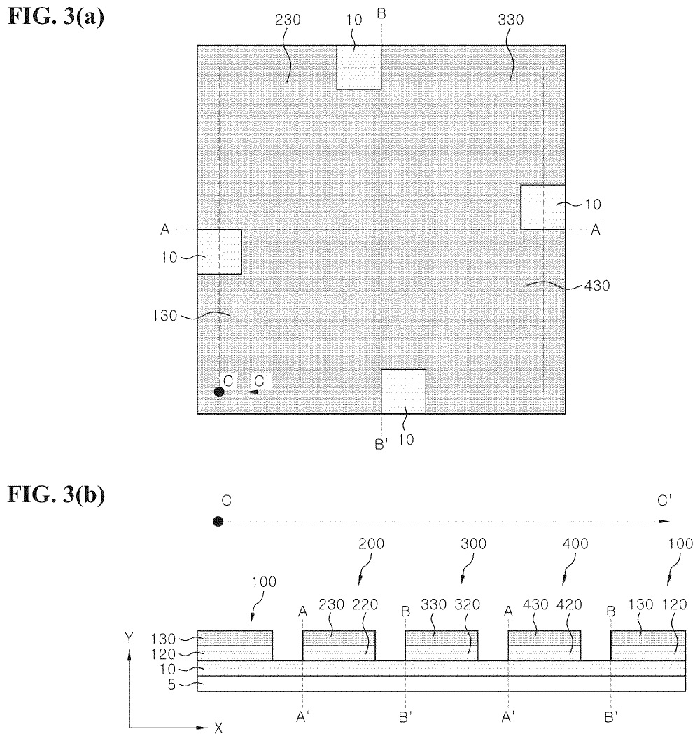

Referring to FIG. 3, mesa etching is performed on the structure of FIG. 2 to expose the n-type semiconductor layer 10. To define the mesa etching area, the sub-pixel is set into four imaginary regions, and the four imaginary regions are divided by imaginary lines A-A′ and B-B′. The imaginary lines are orthogonal to each other and cross at the center of the sub-pixel. A mesa etching region is defined in the upper edge region of the first light emitter 100, and the n-type semiconductor layer 10 is exposed through the mesa etching. In addition, a mesa etching region is defined in the upper right edge region of the second light emitter 200, and the mesa etching region of each light emitter is formed in the corner regions and is formed in the regions that mostly abut the adjacent light emitter. Thus, four mesa etch regions are defined, and the n-type semiconductor layer 10 is exposed in the four mesa etch regions.

By mesa etching, side surfaces of the active layers 120, 220, 320, 420 and p-type semiconductor layers 130, 230, 330, 430 of each of the light emitters 100, 200, 300, 400 may be exposed.

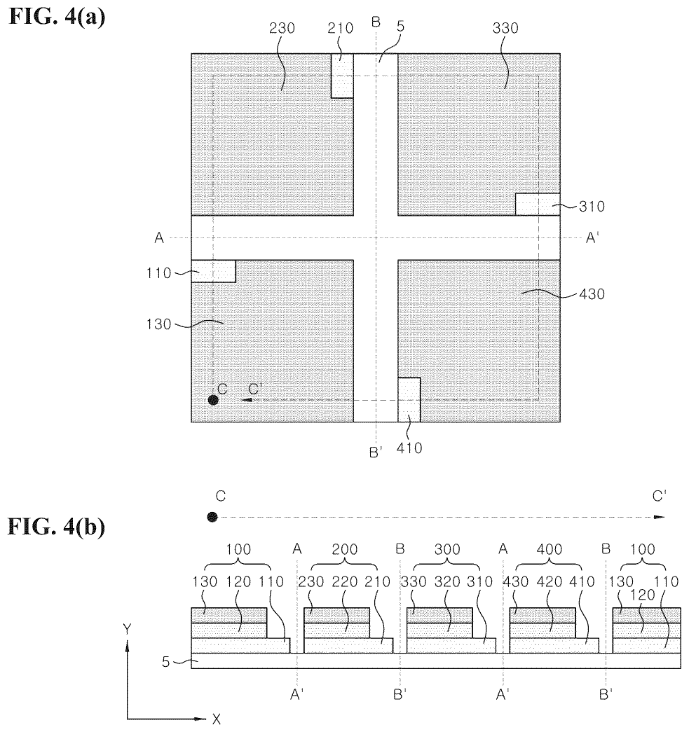

Referring to FIG. 4, an isolation process of the light emitters 100, 200, 300, 400 is performed around the imaginary lines A-A′ and B-B′ through an isolation process such as etching. In this way, the light emitters 100, 200, 300, 400 are each completely isolated, and the first light emitter 100 to the fourth light emitter 400 are defined. Thus, a portion of the surface of the substrate 5 is exposed through the gap spaces between the four light emitters 100, 200, 300, 400. In addition, the n-type semiconductor layers exposed by mesa etching are also completely isolated. Thus, the first n-type semiconductor layer 110 to the fourth n-type semiconductor layer 410 are separately formed.

As shown in FIG. 4(a) above, the second light emitter 200 has the same shape as the first light emitter 100 rotated 90 degrees clockwise. The same applies to the other light emitters, and it is preferred that the four light emitters 100, 200, 300, 400 are formed symmetrically with respect to each other about imaginary centerlines of the sub-pixel.

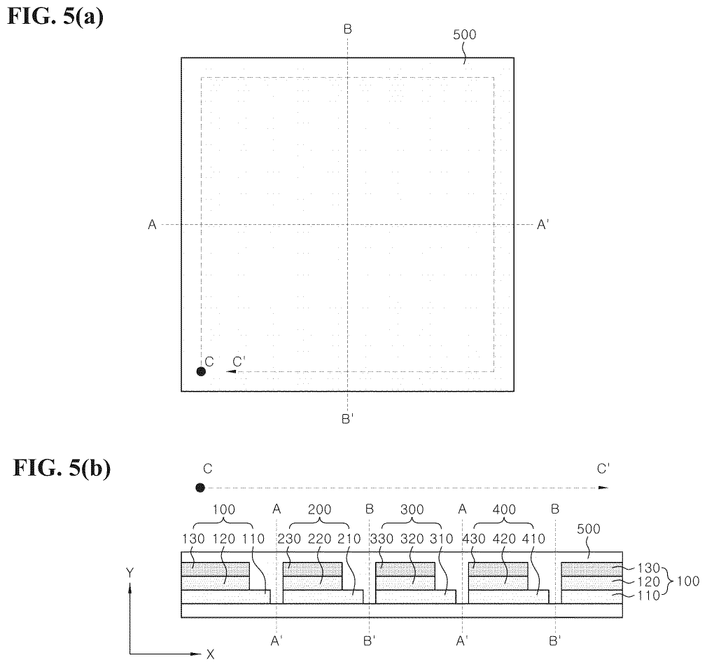

Referring now to FIG. 5, a first insulating layer 500 is formed by conformal deposition of an insulating material on the structure of FIG. 4. The first insulating layer 500 can be any material having insulating properties. For example, the first insulating layer 500 may be but is not necessarily limited to SiO₂, SiNₓ, or Al₂O₃. The first insulating layer 500 completely shields a portion of the substrate 5 and the n-type semiconductor layers 110, 210, 310, 410 exposed in FIG. 4 by burying the gap spaces between the light emitters 100, 200, 300, 400. Furthermore, the first insulating layer 500 completely shields the p-type semiconductor layers 130, 230, 330, 430 at the uppermost portion of each of the light emitters 100, 200, 300, 400.

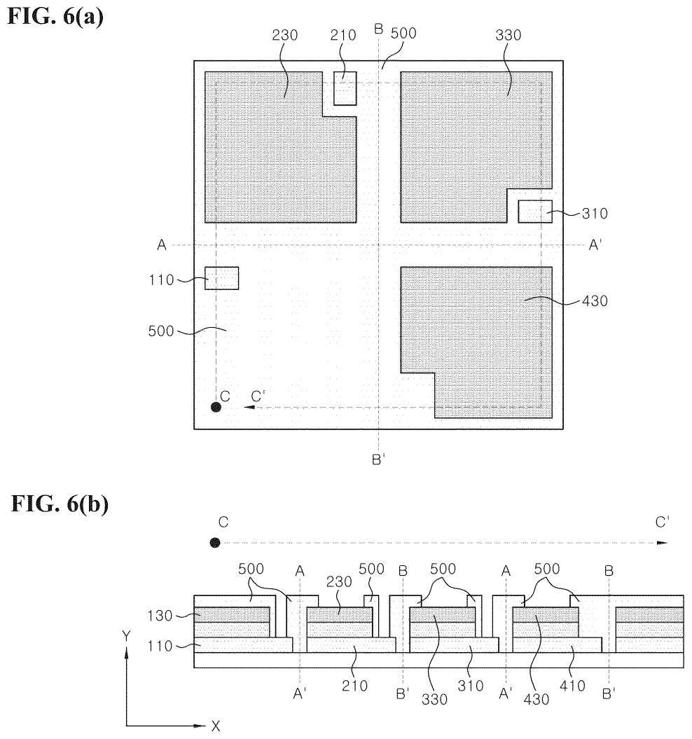

Referring to FIG. 6, a photoresist pattern is formed on the structure of FIG. 5 by a conventional photolithography process, and a selective etching process is performed with the photoresist pattern as an etch mask. Through the selective etching process, a surface portion of the first n-type semiconductor layer 110 to the third n-type semiconductor layer 310 is exposed, and a surface portion of the second p-type semiconductor layer 230 to the fourth p-type semiconductor layer 430 is exposed.

Further, the first p-type semiconductor layer 130 is shielded and not open, and the fourth n-type semiconductor layer 410 of the fourth light emitter 400 is also shielded and not open.

Referring to FIG. 6(a), the opened second p-type semiconductor layer 230 and the opened fourth p-type semiconductor layer 430 have a larger area than the opened n-type semiconductor layers. This is related to the wiring process introduced in a later step. In general, it is preferred that the p-type semiconductor layers are opened and wired with a larger area than the n-type semiconductor layers.

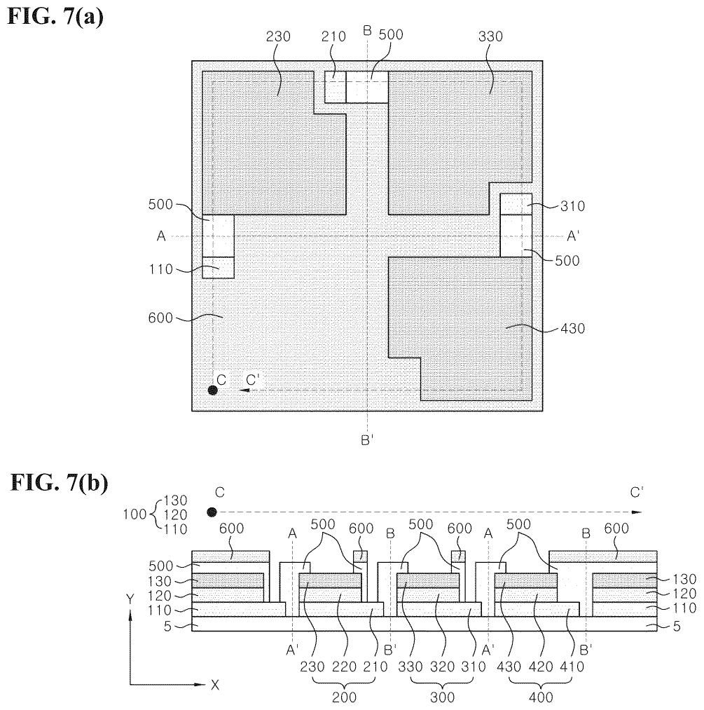

Referring to FIG. 7, a first lift-off layer 600 is formed on a portion of the remaining first insulating layer 500. For the formation of the first lift-off layer 600, a photoresist is applied, and a photoresist pattern is formed by patterning. The first lift-off layer 600 shields the first insulating layer 500 on the first p-type semiconductor layer 130, the first insulating layer 500 between the second p-type semiconductor layer 230 and the second n-type semiconductor layer 210, and the first insulating layer 500 between the third p-type semiconductor layer 330 and the third n-type semiconductor layer 310.

Thus, through the introduction of the first lift-off layer 600, the first n-type semiconductor layer 110 to the third n-type semiconductor layer 310 are opened, and the second p-type semiconductor layer 230 to the fourth p-type semiconductor layer 430 are opened. In addition, the first insulating layer 500 between the first n-type semiconductor layer 110 and the second p-type semiconductor layer 230, the first insulating layer 500 between the second n-type semiconductor layer 210 and the third p-type semiconductor layer 330, and the first insulating layer 500 between the third n-type semiconductor layer 310 and the fourth p-type semiconductor layer 430 are also exposed.

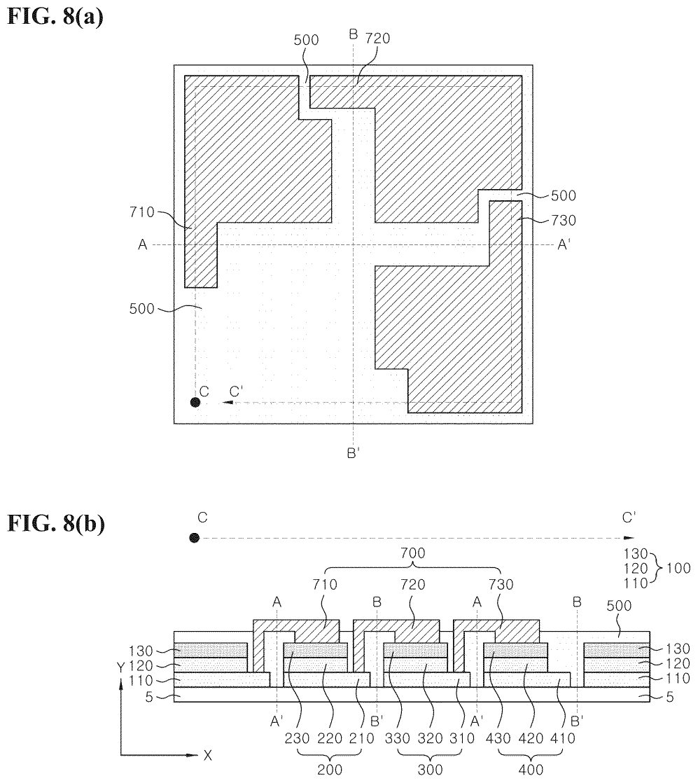

Referring to FIG. 8, a conformal deposition of a wiring material is performed on the structure of FIG. 7 to form the wiring layer 700. A metal is deposited that is conductive, and a lift-off process is performed on the first lift-off layer 600. Thus, a first wiring 710 electrically connecting the first n-type semiconductor layer 110 and the second p-type semiconductor layer 230, a second wiring 720 connecting the second n-type semiconductor layer 210 and the third p-type semiconductor layer 330, and a third wiring 730 connecting the third n-type semiconductor layer 310 and the fourth p-type semiconductor layer 430 are formed. This forms a wiring layer 700 comprising the first wiring 710 to the third wiring 730. The wiring layer 700 diode-connects the first n-type semiconductor layer 110 of the first light emitter 100 to the fourth p-type semiconductor layer 430 of the fourth light emitter 400 in series.

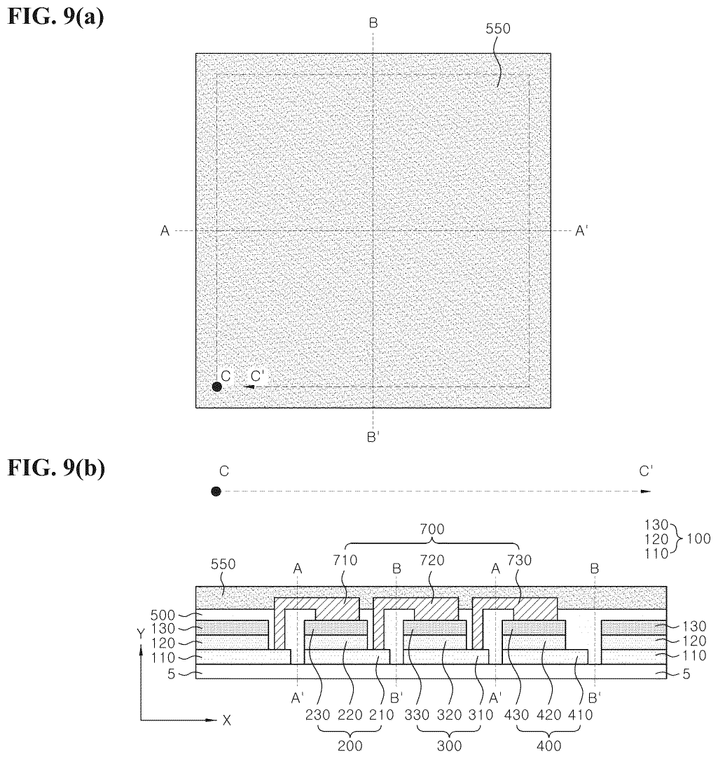

Referring to FIG. 9, a second insulating layer 550 is formed by a conformal deposition of an insulating material. The second insulating layer 550 preferably completely shields the top of the exposed wiring layer 700 and the first insulating layer 500.

Furthermore, the second insulating layer 550 is not particularly limited as long as it is made of a material having insulating properties, and SiO₂, SiNₓ, or Al₂O₃ may be used. Preferably, the second insulating layer 550 is made of the same material as the first interlayer insulating film 500.

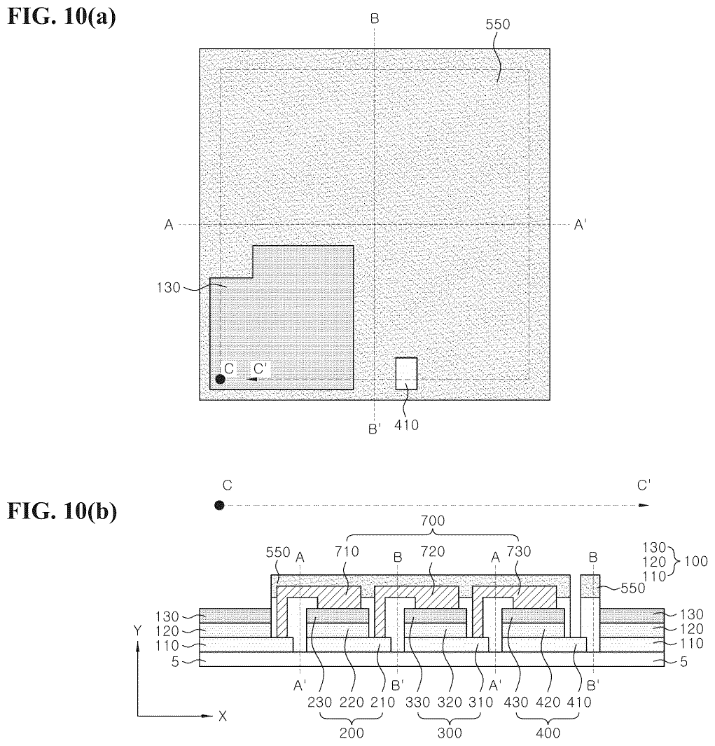

Referring to FIG. 10, a portion of the fourth n-type semiconductor layer 410 of the fourth light emitter 400 is exposed by etching the structure of FIG. 9, and the first p-type semiconductor layer 130 of the first light emitter 100 is exposed.

A photoresist is applied for an etching process, and a photoresist pattern is formed on the areas other than the first p-type semiconductor layer 130 and the fourth n-type semiconductor layer 410 through a conventional photolithography process. Subsequently, the first insulating layer and the second insulating layer on the first p-type semiconductor layer 130 and the fourth n-type semiconductor layer 410 are removed through an etching process.

Through said etching process, at least a portion of the upper surface of the first p-type semiconductor layer 130 and the fourth n-type semiconductor layer 410 is exposed.

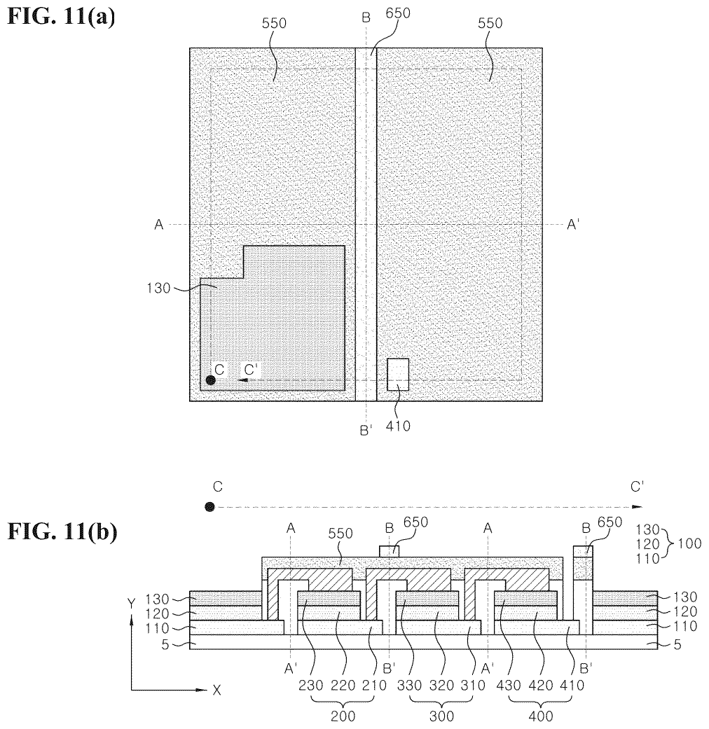

Referring now to FIG. 11, a second lift-off layer 650 is formed on the structure of FIG. 10. The second lift-off layer 650 is similarly or identically constructed of photoresist as the first lift-off layer.

The second lift-off layer 650 is formed in the form of a straight line along lines B-B′ as shown in (a) of FIG. 11. For example, the second lift-off layer 650 is formed along the spacing between the aggregate of the first light emitter 100 and the second light emitter 200 and the aggregate of the third light emitter 300 and the fourth light emitter 400. Thus, as shown in FIG. 11(a), the formation of the second lift-off layer 650 results in a structure in which the first light emitter 100 and the second light emitter 200 are arranged on the left side and the third light emitter 300 and the fourth light emitter 400 are arranged on the right side, i.e., the second lift-off layer 650 bisects the sub-pixel.

Also, while the cross-sectional view of FIG. 11(b) shows the second lift-off layer 650 as being separate from each other, that is for illustrative purposes only, and it is clear that they are one structure as shown in FIG. 11(a).

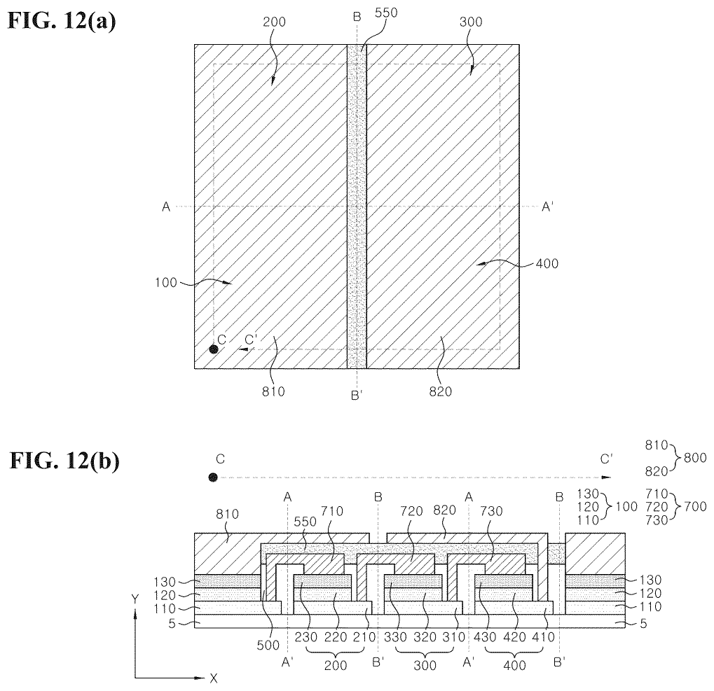

Referring now to FIG. 12, a deposition and lift-off process of metal on the structure of FIG. 11 is performed. Through deposition, an anode 810 covering the opened first p-type semiconductor layer 130 and the top surface of the second light emitter 200 is formed, and a cathode 820 covering the fourth n-type semiconductor layer 430 and the top surface of the third light emitter 300 and the fourth light emitter 400 is formed. Thereby, the electrode layer 800 is formed. This is the same as shown in FIG. 1. The electrode-forming process is completed by forming anode 810 and cathode 820.

Furthermore, the metal formed on the second lift-off layer is removed by the lift-off process. Thus, the anode 810 and cathode 820 are completely separated around the imaginary line B-B′. Thereby, the unit sub-pixel of FIG. 1 or FIG. 12 is produced.

In the above-described inventive concept, the unit sub-pixel generating a certain color among red, green and blue is divided into four light emitters, and a series-connected structure of diodes is implemented between them. The first p-type semiconductor layer of the first light emitter is electrically connected with the anode, and the fourth n-type semiconductor layer of the fourth light emitter is electrically connected with the cathode. This allows the four light emitters to be modeled as four diodes connected in series. The four light emitters are formed sequentially in a clockwise or counterclockwise direction when the unit sub-pixel is separated into four equal regions.

Furthermore, each emitter has a shape that is rotated 90 degrees from its neighboring emitters. In particular, the region of the n-type semiconductor layers exposed by the mesa etching of each light emitter is preferably arranged in a corner region, close to the neighboring light emitters. This enables an effective wiring process to be performed, that is, the wiring process performs an electrical connection from the first n-type semiconductor layer of the first light emitter to the fourth p-type semiconductor layer of the fourth light emitter.

Further, through the electrode-forming process, the first p-type semiconductor layer is electrically connected with the anode, and the fourth n-type semiconductor layer is electrically connected with the cathode.

In the present inventive concept, a roughly rectangular unit sub-pixel is divided into four light emitters having the same area with each other. The four divided light emitters are electrically connected in series. Thus, the voltage for turning on one unit sub-pixel has a higher value than for the case where the unit sub-pixel is not divided. If the turn-on voltage of a unit sub-pixel is increased, power-consumption efficiency of the unit sub-pixel is increased. Furthermore, optical efficiency is also increased.

In another example of the present inventive concept, the unit sub-pixel may be divided into two or three light emitters having mutually equal areas.

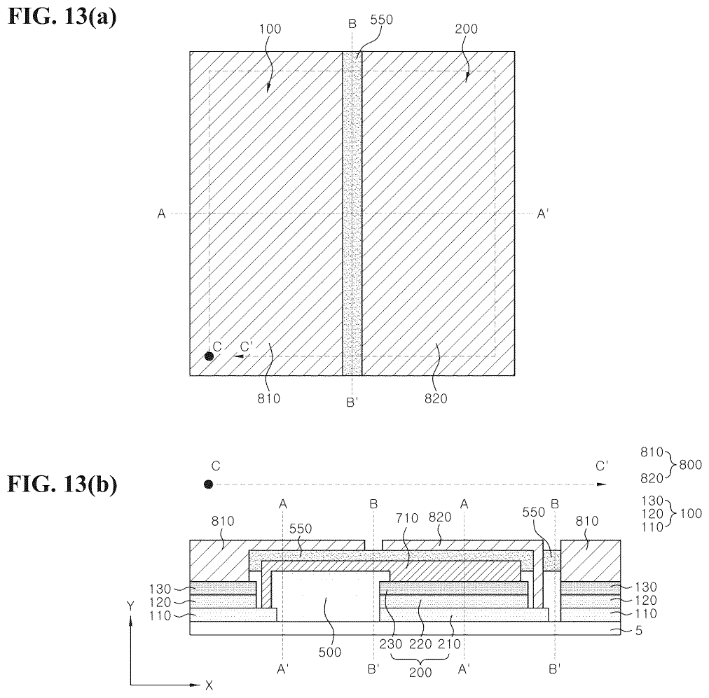

FIG. 13 is a top plan view and a cross-sectional view of a sub-pixel divided into two light emitters according to another embodiment of the present inventive concept.

Referring to FIG. 13, The two light emitters 100, 200 have identical shapes and are opposed to each other around lines B-B′ on substrate 5. Furthermore, the first n-type semiconductor layer 110 of the first light emitter 100 is connected to the second p-type semiconductor layer 230 of the second light emitter 200. For the connection, a first wiring 710 is utilized, i.e., in the cross-sectional view of FIG. 13, an anode 810 is formed while covering the first light emitter 100, and a cathode 820 is connected to the second n-type semiconductor layer 210, covering the second light emitter 200. This is a configuration in which the second light emitter and the third light emitter are omitted in FIG. 1, the first light emitter is divided into unit subpixels, and the second light emitter has a symmetrical structure with the first light emitter.

Furthermore, in FIG. 13, the first light emitter 100 corresponds to the light emitter at the fore-end and the second light emitter 200 corresponds to the light emitter at the tail-end. The light emitter at the fore-end is connected to the anode 810, and the light emitter at the tail-end is connected to the cathode 820.

Other stacking structures are the same as indicated by the reference numerals of FIG. 1 through FIG. 12.

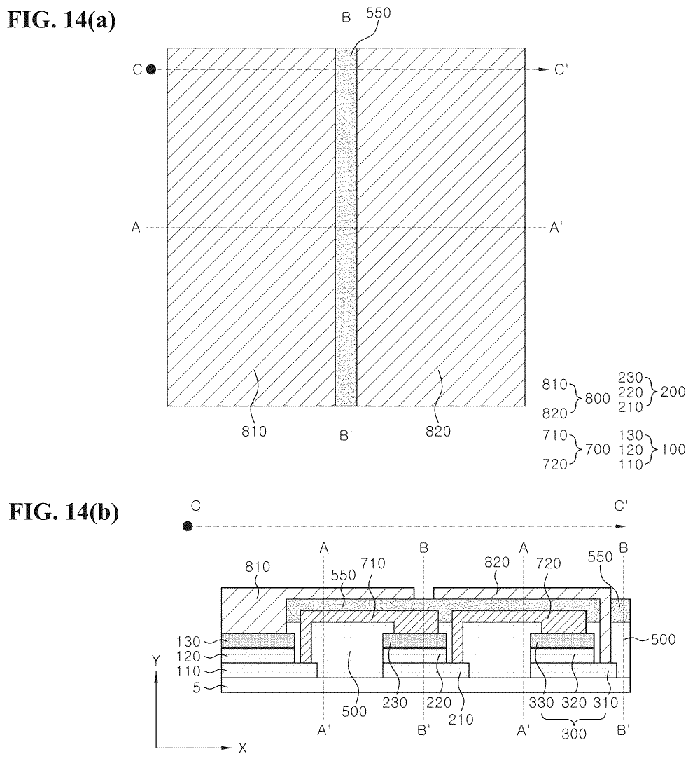

FIG. 14 is a top plan view and cross-sectional view of a sub-pixel divided into three light emitters, according to still another embodiment of the present inventive concept.

Referring to FIG. 14, a sub-pixel has three divided light emitters 100, 200, and 300, i.e., a first light emitter 100, a second light emitter 200, and a third light emitter 300 are formed side-by-side but spaced apart. An anode 810 is formed on the first p-type semiconductor layer 130 of the first light emitter 100, and the first n-type semiconductor 110 is connected to the second p-type semiconductor layer 230 of the second light emitter 200 via the first wiring 710. Further, the second n-type semiconductor layer 210 of the second light emitter 200 is connected to the third p-type semiconductor layer 330 of the third light emitter 300 via the second wiring 720. Furthermore, a cathode 820 is formed on the third n-type semiconductor layer 310, and the cathode 820 is formed covering the third light emitter 300. Thus, the first light emitter 100 corresponds to the light emitter at the fore-end, and the third light emitter 300 corresponds to the light emitter at the tail-end. The light emitter at the fore-end is electrically connected to the anode 810, and the light emitter is electrically connected to the cathode 820. The anode 810 and cathode 820 are connected to a power source to drive the unit sub-pixel.

FIGS. 13 and 14 illustrate variations of the present inventive concept, wherein a unit sub-pixel formed on the same substrate may have more or less than four light emitters.

In addition, the three divided light emitters 100, 200, 300 in FIG. 14 may have the same shape and symmetrical structure from each other, or they may have different shapes, i.e., a unit sub-pixel having a few micro-sizes or tens of micro-sizes on the substrate is separated into a plurality of light emitters, and the separated light emitters are connected via a wiring layer 700. The wiring layer 700 is formed on the first insulating layer 500, and the electrodes 800 are formed on the second insulating layer 550 formed on the wiring layer 700.

The presently described inventive concept can improve power-consumption efficiency in a unit sub-pixel, which is one element of a unit pixel of the micro-LED. Furthermore, a wiring layer and an electrode layer are formed on top of at least one light emitter, and the light generated by the light emitter is reflected by the electrode layer and directed to the substrate. This is a kind of flip-chip type, and light can be effectively emitted through the substrate. In addition, as the unit sub-pixel is separated and the wiring process proceeds, the operating voltage of the unit sub-pixel can be easily increased because a transfer process for a plurality of separate light emitters is not required.

1. A unit sub-pixel having a square shape, the unit sub-pixel comprising:
a first light emitter electrically connected to an anode connected to an external power source;
a second light emitter having the shape of the first emitter rotated by 90 degrees, formed in a region adjacent to the first light emitter, and electrically connected to the first light emitter;
a third light emitter having the shape of the second emitter rotated by 90 degrees, formed in a region adjacent to the second light emitter, and electrically connected to the second light emitter; and
a fourth light emitter having the shape of the third emitter rotated by 90 degrees, formed in a region adjacent to the third light emitter, and electrically connected to the third light emitter,
wherein the four light emitters form light of the same wavelength, and the first light emitter and the second light emitter are opposite to the third light emitter and the fourth light emitter.

2. The unit sub-pixel of claim 1, wherein the four light emitters are formed on the same substrate.

3. The unit sub-pixel of claim 2, wherein the first light emitter to the fourth light emitter respectively includes:
a n-type semiconductor layer formed on the substrate;
an active layer formed on the n-type semiconductor layer; and
a p-type semiconductor layer formed on the active layer,
wherein the anode is electrically connected to the first p-type semiconductor layer of the first light emitter, and the cathode is connected to the fourth n-type semiconductor layer of the fourth light emitter.

4. The unit sub-pixel of claim 3 further comprises a first insulating layer that buries the gap spaces between the first light emitter to the fourth light emitter and buries the upper portion of the first light emitter to the fourth light emitter.

5. The unit sub-pixel of claim 4 further comprises,
a first wiring connecting the first n-type semiconductor layer of the first light emitter to the second p-type semiconductor layer of the second light emitter by penetrating the first insulating layer;
a second wiring connecting the second n-type semiconductor layer of the second light emitter to the third p-type semiconductor layer of the third light emitter by penetrating the first insulating layer; and
a third wiring connecting the third n-type semiconductor layer of the third light emitter to the fourth p-type semiconductor layer of the fourth light emitter by penetrating the first insulating layer.

6. The unit sub-pixel of claim 5, wherein the first insulating layer blocks the connection between the n-type semiconductor layer and the p-type semiconductor layer in the same light emitter.

7. The unit sub-pixel of claim 5 further comprises a second insulating layer covering an upper surface of the first insulating layer and covering an upper surface of the first wiring to the third wiring.

8. The unit sub-pixel of claim 7, wherein the anode and the cathode penetrate the first insulating layer and the second insulating layer.

9. The unit sub-pixel of claim 3, wherein the anode is formed on the first light emitter and the second emitter, and the cathode is formed on the third light emitter and the fourth light emitter.

10. The unit sub-pixel of claim 9, wherein the anode and the cathode are mutually symmetrical with respect to an imaginary centerline bisecting the unit sub-pixel.

11. A unit sub-pixel comprising:
light emitters formed on same substrate, respectively having n-type semiconductor layer, active layer and p-type semiconductor layer, and isolated from each other;
a first insulating layer covering the upper portion of the light emitters and burying gap spaces between the light emitters;
a wiring layer penetrating the first insulating layer or formed on the first insulating layer to diode-connect the light emitters;
a second insulating layer formed on the wiring layer and on the first insulating layer; and
an electrode layer connecting the light emitters to external power.

12. The unit sub-pixel of claim 11, wherein the light emitters form light of the same wavelength, and each of the light emitters has the same shape,
wherein any one of the light emitters has the same shape rotated by 90 degrees with respect to an adjacent light emitter.

13. The unit sub-pixel of claim 11, wherein the electrode layer includes,
an anode penetrating the first insulating layer and the second insulating layer to be connected to a p-type semiconductor layer of a light emitter at fore-end; and
a cathode penetrating the first insulating layer and the second insulating layer to be connected to an n-type semiconductor layer of a light emitter at tail-end,
wherein the anode covers the upper portion of the light emitter at the fore-end and the cathode covers the upper portion of the light emitter at the tail-end.

14. The unit sub-pixel of claim 13, wherein the wiring layer connects an n-type semiconductor layer of the light emitter at the fore-end to a p-type semiconductor layer of another light emitter adjacent to the light emitter at the fore-end or to a p-type semiconductor layer of the light emitter at the tail-end, and the wiring layer penetrates the first insulating layer.

15. A method of manufacturing a unit sub-pixel comprising:
sequentially forming an n-type semiconductor, an active layer and a p-type semiconductor layer on a substrate;
forming light emitters by etching and separating the n-type semiconductor, the active layer and the p-type semiconductor;
performing a wiring process in which an n-type semiconductor of the light emitter is connected to a p-type semiconductor layer of another light emitter adjacent to the light emitter; and
after the wiring process, performing electrode-forming process in which an anode is formed on the p-type semiconductor layer of the light emitter at fore-end and a cathode is formed on the n-type semiconductor layer of the light emitter at the tail-end adjacent to the light emitter.

16. The method of manufacturing a unit sub-pixel of claim 15, wherein the forming the light emitter includes:
performing mesa etching for the light emitter to expose the n-type semiconductor layer; and
partially etching the exposed n-type semiconductor layer to expose a portion of the substrate and to isolate the light emitters,
wherein each of the isolated light emitters is formed on the same substrate.

17. The method of manufacturing a unit sub-pixel of claim 15, wherein the performing the wiring process includes:
forming a first insulating layer that covers a gap space between the light emitters and upper space of the light emitters;
exposing the p-type semiconductor layer and the n-type semiconductor layer of the light emitters by selectively etching for the first insulating layer; and
forming wiring that connects the exposed n-type semiconductor layer of one light emitter with the p-type semiconductor layer of light emitter adjacent to the one light emitter.

18. The method of manufacturing a unit sub-pixel of claim 17, the method further comprises,
after selectively etching for the first insulating layer, forming a first lift-off layer on the first insulating layer on whose areas the wiring has not been formed.

19. The method of manufacturing a unit sub-pixel of claim 15, wherein the performing the electrode-forming process comprises:
forming a second insulating layer on wiring formed by the wiring process;
exposing the p-type semiconductor of the light emitter at the fore-end and the n-type semiconductor of the light emitter at the tail-end by selectively etching for the second insulating layer; and
forming the anode on the p-type semiconductor of the light emitter at the fore-end and forming the cathode on n-type semiconductor of the light emitter at the tail-end,
wherein the anode and the cathode have the same shape and face each other.

20. The method of manufacturing a unit sub-pixel of claim 19, wherein the anode and the cathode are mutually symmetrical with respect to an imaginary centerline bisecting the unit sub-pixel.
